(19) United States
(12) Patent Application Publication
(10) Pub. No.: US 2023/0073823 A1
(43) Pub. Date: Mar. 9, 2023

(54) PACKAGE COMPRISING A SUBSTRATE WITH HIGH-DENSITY INTERCONNECTS

(71) Applicant: QUALCOMM Incorporated, San Diego, CA (US)

(72) Inventors: Chin-Kwan KIM, San Diego, CA (US); Kuiwon KANG, San Diego, CA (US); Joan Rey Villarba BUOT, Escondido, CA (US)

(21) Appl. No.: 17/471,061

(22) Filed: Sep. 9, 2021

(51) Int. Cl. H01L 23/522; H01L 25/065; H01L 23/528; H01L 23/532; H01L 23/498; H01L 23/538; H01L 23/31; H01L 23/00

(52) U.S. Cl. CPC H01L 23/5226; H01L 25/0655; H01L 23/5283; H01L 23/53295; H01L 23/49816; H01L 23/5389; H01L 23/3107; H01L 24/17; H01L 24/14; H01L 2224/11849; H01L 2224/14104

(57) ABSTRACT

A package comprising a substrate and an integrated device coupled to the substrate. The substrate includes a core layer comprising a first surface and a second surface; at least one first dielectric layer coupled to the first surface of the core layer; at least one second dielectric layer coupled to the second surface of the core layer; at least one core interconnect that extends through the core layer and at least one dielectric layer from the at least first dielectric layer and/or the at least one second dielectric layer; a plurality of high-density interconnects comprising a first minimum width and a first minimum spacing; and a plurality of interconnects comprising a second minimum width and a second minimum spacing. The second minimum width is greater than the first minimum width. The second minimum spacing is greater than the first minimum spacing.

### FIELD

Various features relate to packages with a substrate and an integrated device.

### BACKGROUND

A package may include a substrate and integrated devices. These components are coupled together to provide a package that may perform various electrical functions. How the integrated devices and the substrate are coupled together affects how the package performs overall. There is an ongoing need to provide better performing packages and reduce the overall size of packages.

### SUMMARY

Various features relate to packages with a substrate and an integrated device.

One example provides a package comprising a substrate and an integrated device coupled to the substrate. The substrate includes a core layer comprising a first surface and a second surface; at least one first dielectric layer coupled to the first surface of the core layer; at least one second dielectric layer coupled to the second surface of the core layer; at least one core interconnect that extends through the core layer and at least one dielectric layer from the at least first dielectric layer and/or the at least one second dielectric layer; a plurality of high-density interconnects comprising a first minimum width and a first minimum spacing; and a plurality of interconnects comprising a second minimum width and a second minimum spacing. The second minimum width is greater than the first minimum width. The second minimum spacing is greater than the first minimum spacing.

Another example provides a substrate that includes a core layer comprising a first surface and a second surface; at least one first dielectric layer coupled to the first surface of the core layer; at least one second dielectric layer coupled to the second surface of the core layer; at least one core interconnect that extends through the core layer and at least one dielectric layer from the at least first dielectric layer and/or the at least one second dielectric layer; a plurality of high-density interconnects comprising a first minimum width and a first minimum spacing; and a plurality of interconnects comprising a second minimum width and a second minimum spacing. The second minimum width is greater than the first minimum width. The second minimum spacing is greater than the first minimum spacing.

Another example provides an apparatus comprising a substrate and an integrated device coupled to the substrate. The substrate includes a core layer comprising a first surface and a second surface; at least one first dielectric layer coupled to the first surface of the core layer; at least one second dielectric layer coupled to the second surface of the core layer; means for core interconnection that extends through the core layer and at least one dielectric layer from the at least first dielectric layer and/or the at least one second dielectric layer; means for high-density interconnection comprising a first minimum width and a first minimum spacing; and means for interconnection comprising a second minimum width and a second minimum spacing. The second minimum width is greater than the first minimum width. The second minimum spacing is greater than the first minimum spacing.

Another example provides a method for fabricating a substrate. The method provides a core layer comprising a first surface and a second surface. The method provides at least one first dielectric layer and a plurality of high-density interconnects over the first surface of the core layer. The plurality of high-density interconnects comprises a first minimum width and a first minimum spacing. The method forms at least one second dielectric layer over the second surface of the core layer. The method forms at least one core interconnect that extends through the core layer and at least one dielectric layer from the at least first dielectric layer and/or the at least second dielectric layer. The method forms a plurality of interconnects comprising a second minimum width and a second minimum spacing. The second minimum width is greater than the first minimum width. The second minimum spacing is greater than the first minimum spacing.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of a package that includes a cored substrate with high-density interconnects.

FIG. 2 illustrates a cross sectional profile view of a package that includes another cored substrate with high-density interconnects.

FIG. 3 illustrates a plan view of a package that includes a cored substrate with high-density interconnects.

FIG. 4 illustrates an exemplary sequence for fabricating an embedded trace substrate (ETS) layer with high-density interconnects.

FIG. 5 illustrates an exemplary flow diagram of a method for fabricating an embedded trace substrate (ETS) layer with high-density interconnects.

FIGS. 6A-6D illustrate an exemplary sequence for fabricating a cored substrate with high-density interconnects.

FIG. 7 illustrates an exemplary flow diagram of a method for fabricating a cored substrate with high-density interconnects.

FIGS. 8A-8B illustrate an exemplary sequence for fabricating a package that includes a cored substrate with high-density interconnects.

FIG. 9 illustrates an exemplary flow diagram of a method for fabricating a package that includes a cored substrate with high-density interconnects.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate and an integrated device coupled to the substrate. The substrate includes a core layer comprising a first surface and a second surface, at least one first dielectric layer coupled to the first surface of the core layer, at least one second dielectric layer coupled to the second surface of the core layer, at least one core interconnect that extends through the core layer and at least one dielectric layer from the at least first dielectric layer and/or the at least one second dielectric layer, a plurality of high-density interconnects comprising a first minimum width and a first minimum spacing, and a plurality of interconnects comprising a second minimum width and a second minimum spacing. The second minimum width is greater than the first minimum width. The second minimum spacing is greater than the first minimum spacing. The package may include a second integrated device. The second integrated is configured to be electrically coupled to the integrated device through the plurality of high-density interconnects. The plurality of high-density interconnects may be configured as bridge interconnects between two integrated devices. The high-density interconnects allow more interconnects (e.g., higher density routing) to be implemented in a package. The high-density interconnects may allow faster communication (e.g., electrical communication) between integrated devices of a package. The high-density interconnects may allow packages with smaller footprints, while still providing improved package performance

### Exemplary Package Comprising a Substrate Having a High-Density Interconnects

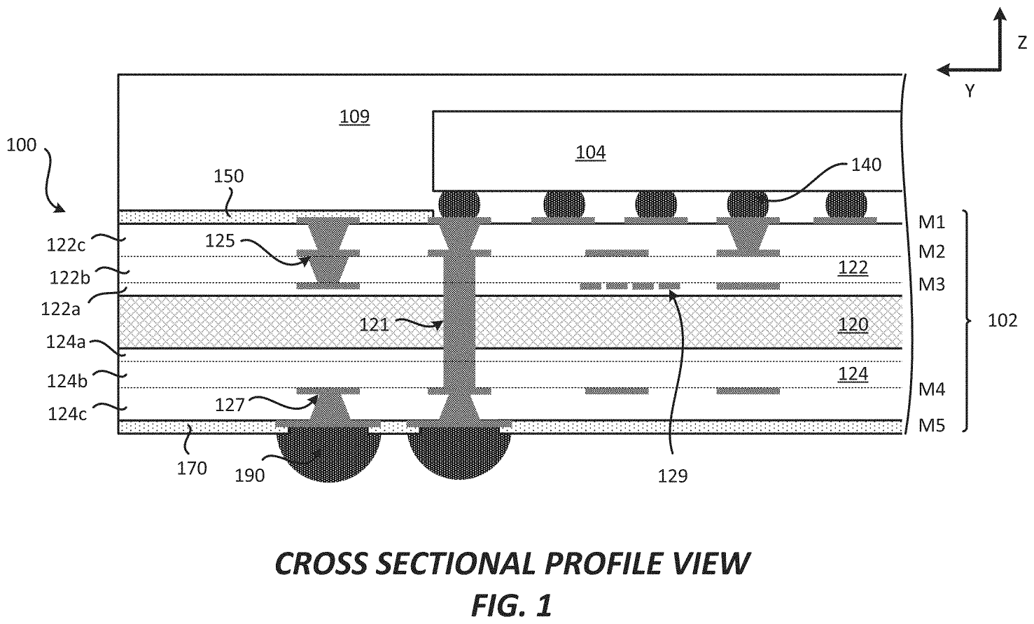

FIG. 1 illustrates a cross sectional profile view of a package 100 that includes a substrate (e.g., cored substrate) with high-density interconnects. The package 100 includes a substrate 102, an integrated device 104 and an encapsulation layer 108. The package 100 may include more than one integrated device coupled to the substrate 102.

The integrated device 104 is coupled to a first surface of the substrate 102 through a plurality of solder interconnects 140. For example, the integrated device 104 is coupled to a plurality of interconnects 125 through the plurality of solder interconnects 140. The encapsulation layer 109 is located over the substrate 102 and the integrated device 104. The encapsulation layer 109 may encapsulate the integrated device 104. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. A plurality of solder interconnects 190 is coupled to the substrate 102. For example, the plurality of solder interconnects 190 is coupled to the plurality of interconnects 127.

The substrate 102 may be a cored substrate. The substrate 102 includes a core layer 120, at least one dielectric layer 122, at least one dielectric layer 124, at least one core interconnect 121, a plurality of interconnects 125, a plurality of interconnects 127, a plurality of high-density interconnects 129, a solder resist layer 150, and a solder resist layer 170. The at least one dielectric layer 122 may be an at least one first dielectric layer. The at least one dielectric layer 124 may be an at least one second dielectric layer.

The core layer 120 may include different dielectric materials, such a silicon, glass, quartz, epoxy, or combinations thereof. The at least one dielectric layer 122 is coupled to and formed over a first surface (e.g., top surface) of the core layer 120. The at least one dielectric layer 122 may include a dielectric layer 122a, a dielectric layer 122b, and a dielectric layer 122c. The dielectric layer 122a, the dielectric layer 122b, and/or the dielectric layer 122c may be considered as one dielectric layer. The at least one dielectric layer 124 is coupled to and formed over a second surface (e.g., bottom surface) of the core layer 120. The at least one dielectric layer 124 may include a dielectric layer 124a, a dielectric layer 124b, and a dielectric layer 124c. The dielectric layer 124a, the dielectric layer 124b, and/or the dielectric layer 124c may be considered as one dielectric layer. Examples of a dielectric layer (e.g., 122, 124) include prepreg and/or Ajinomoto Build-up Film “ABF”. The solder resist layer 150 is located over the at least one dielectric layer 122. The solder resist layer 170 is located over the at least one dielectric layer 124.

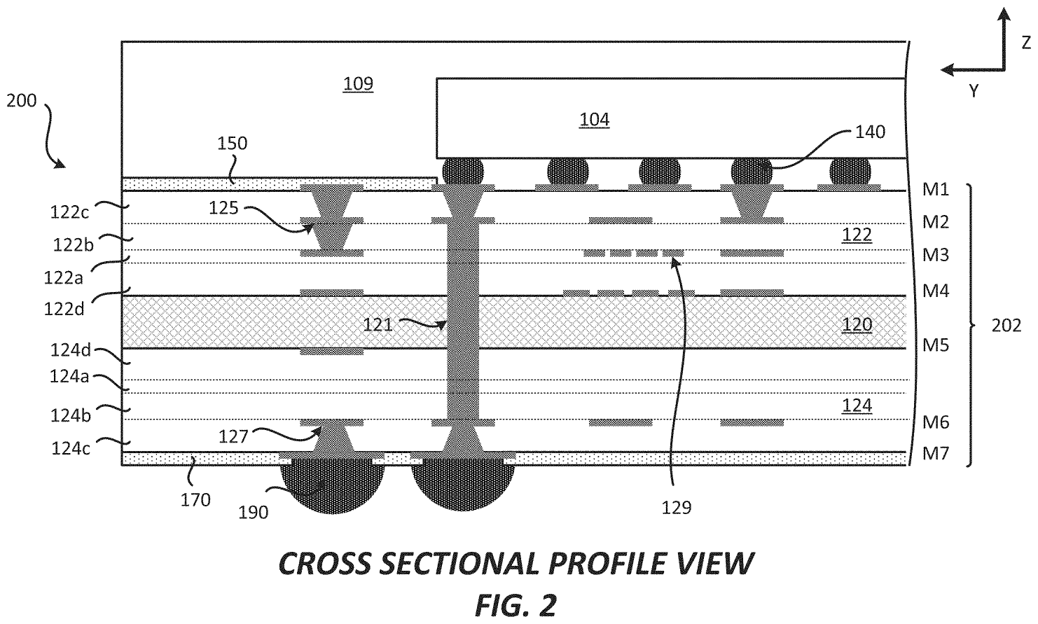

The at least one core interconnect 121 may extend through the core layer 120 and at least one dielectric layer from the at least one dielectric layer 122 and/or the at least one dielectric layer 124. The at least one core interconnect 121 may be a means for core interconnection. The at least one core interconnect 121 may include a core via that extends through the core layer 120 and at least one dielectric layer from the at least one dielectric layer 122 and/or the at least one dielectric layer 124. In the example of FIG. 2, the at least one core interconnect 121 (e.g., core via, core via interconnect) extends through the dielectric layer 122b, the dielectric layer 122a, the core layer 120, the dielectric layer 124a and the dielectric layer 124b. The at least one core interconnect 121 may be a means for core interconnection.

The plurality of high-density interconnects 129 may be located in and/or over the at least one dielectric layer 122. The plurality of high-density interconnects 129 may be a means for high-density interconnection. The plurality of high-density interconnects 129 may comprise a first minimum width (W) and a first minimum spacing (S). In some implementations, the first minimum width may be in a range of 3-4 micrometers. In some implementations, the first minimum spacing may be in a range of 3-4 micrometers. The plurality of high-density interconnects 129 may comprise a first width in a range of 3-4 micrometers. The plurality of high-density interconnects 129 may comprise a first spacing in a range of 3-4 micrometers. The plurality of high-density interconnects 129 may comprise a thickness of about 0.5-1 micrometer. The plurality of high-density interconnects 129 may be fabricated using an embedded trace substrate (ETS) process. The plurality of high-density interconnects 129 may be part of an ETS layer of the substrate 102. As will be further described below, a substrate may include one or more ETS layer comprising high-density interconnects. It is noted that in some implementations, interconnects that are located on the same metal layer as the plurality of high-density interconnects 129 may have minimum width and/or minimum spacing that are greater than the first minimum width and/or greater than the first minimum spacing.

The plurality of interconnects 125 may be located in and/or over the at least one dielectric layer 122. The plurality of interconnects 127 may be located in and/or over the at least one dielectric layer 124. The plurality of interconnects 125 and/or the plurality of interconnects 127 may be a means for interconnection. The plurality of interconnects 125, the plurality of interconnects 127 and/or the at least one core interconnect 121 may comprise a second minimum width (W) and a second minimum spacing (S). In some implementations, the second minimum width may be 5 micrometers or greater. In some implementations, the first minimum spacing may be 5 micrometers or greater. The plurality of interconnects 125, the plurality of interconnects 127 and/or the at least one core interconnect 121 may comprise a second width (W) that is 5 micrometers or greater. The plurality of interconnects 125, the plurality of interconnects 127 and/or the at least one core interconnect 121 may comprise a second spacing (S) that is 5 micrometers or greater. The plurality of interconnects 125 and/or the plurality of interconnects may be a means for interconnection.

In some implementations, the plurality of interconnects 125 may include interconnects that are located on the same metal layer as the plurality of high-density interconnects 129.

In some implementations, the second minimum width is greater than the first minimum width. In some implementations, the second minimum spacing is greater than the first minimum spacing. The plurality of high-density interconnects 129 may have able to have smaller width and/or spacing because the plurality of high-density interconnects 129 is fabricated using a different process than the process that is used to fabricate the plurality of interconnects 125, the plurality of interconnects 127 and/or the at least one core interconnect 121. As will be further described below, the package may combine different fabrication processes for different interconnects in order to fabricate the plurality of high-density interconnects 129 and the plurality of interconnects (e.g., 125, 127) for the substrate 102.

FIG. 1 illustrates a substrate 102 that includes 5 metal layers (e.g., M1, M2, M3, M4, M5). In the example of FIG. 1, the M3 and M4 layers are not located on surface(s) of the core layer 120. FIG. 1 also illustrates that the plurality of high-density interconnects 129 is located on the M3 metal layer of the substrate 102. It is noted that the plurality of high-density interconnects 129 may be located on multiple metal layers and/or on different metal layers of a substrate. FIG. 1 illustrates that the plurality of high-density interconnects 129 is located on a metal layer that is the next metal layer over the core layer 120. In some implementations, the plurality of high-density interconnects 129 may be located differently in a substrate. FIG. 1 illustrates a substrate 102 that is asymmetrical in terms of the number of metal layers. That is, one side of the core layer 120 has a different number of metal layers than another side of the core layer 120. The substrate 102 has three metal layers over one side of the core layer 120, and 2 metal layers over the other side of the core layer 120. It is noted that different implementations may have different configurations in the number of metal layers. In some implementations, the bottom side of the core layer 120 may have more metal layers than the top side of the core layer 120.

FIG. 2 illustrates a package 200 that includes a substrate 202 and the integrated device 104. The package 200 is similar to the package 100, and thus includes similar components and/or configurations as described for the package 100.

The substrate 202 is similar to the substrate 102. The substrate 202 may be a cored substrate. The substrate 202 includes the core layer 120, at least one dielectric layer 122, at least one dielectric layer 124, at least one core interconnect 121, a plurality of interconnects 125, a plurality of interconnects 127, a plurality of high-density interconnects 129, a solder resist layer 150, and a solder resist layer 170. The substrate 202 includes more metal layers (e.g., M1, M2, M3, M4, M5, M6, M7) than the substrate 102. In the example of FIG. 2, the M4 and M5 layers are located on surface(s) of the core layer 120.

The at least one dielectric layer 122 is coupled to and formed over a first surface of the core layer 120. The at least one dielectric layer 122 may include a dielectric layer 122a, a dielectric layer 122b, a dielectric layer 122c, and a dielectric layer 122d. The dielectric layer 122a, the dielectric layer 122b, the dielectric layer 122c and/or the dielectric layer 122d may be considered as one dielectric layer. The at least one dielectric layer 124 is coupled to and formed over a second surface of the core layer 120. The at least one dielectric layer 124 may include a dielectric layer 124a, a dielectric layer 124b, a dielectric layer 124c, and a dielectric layer 124d. The dielectric layer 124a, the dielectric layer 124b, the dielectric layer 124c, and/or the dielectric layer 124d may be considered as one dielectric layer.

FIG. 2 illustrates that the plurality of high-density interconnects 129 is located on the M3 metal layer of the substrate 202. However, it is noted that the plurality of high-density interconnects 129 may be located on multiple metal layers and/or on different metal layers of a substrate. The widths, the spacings, the minimum widths and/or minimum spacings of the interconnects, as described in FIG. 1 may also be applicable to various interconnects and/or high-density interconnects of FIG. 2.

FIGS. 1 and 2 illustrate high-density interconnects (e.g., 129) located in the dielectric layer 122. However, high-density interconnects may also be located in the dielectric layer 124. Thus, for example, high-density interconnects (e.g., 129) may also be located in the M4 metal layer of the substrate 102. Similarly, in some implementations, high-density interconnects (e.g., 129) may also be located in the M5 metal layer and/or the M6 metal layer of the substrate 202. It is noted that the labeling of the metal layers may differ for different implementations. It is noted that there may be residual metal on other metal layers. However, such layers with residual metal may not be considered a metal layer for the substrate.

As will be further described below, one advantage of using high-density interconnects is the ability to provide bridge interconnects between integrated devices. These high-density interconnects may be used to provide high density electrical routing (e.g., high-capacity electrical communication) between integrated devices.

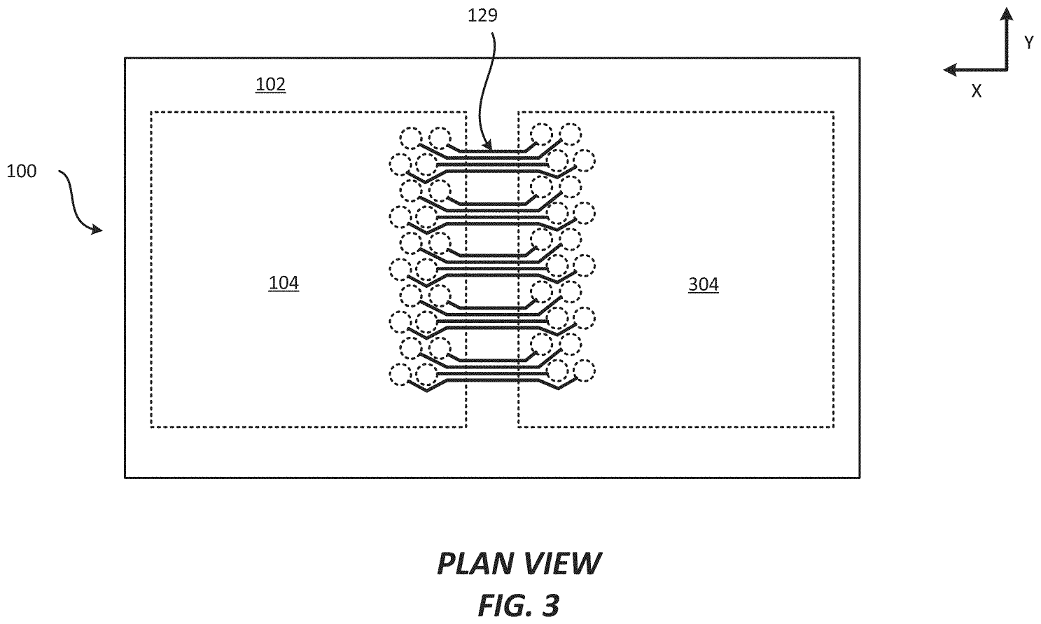

FIG. 3 illustrates a plan view of the package 100 that includes the substrate 102, the integrated device 104 (e.g., first integrated device), an integrated device 304 (e.g., second integrated device), and the plurality of high-density interconnects 129. The plurality of high-density interconnects 129 may be located in any metal layer(s) of the substrate 102. The plurality of high-density interconnects 129 is configured to operate as a plurality of bridge interconnects between the integrated device 104 and the integrated device 304. The plurality of high-density interconnects 129 may be configured to provide high-capacity electrical communication between the integrated device 104 and the integrated device 304. In some implementations, the plurality of high-density interconnects 129 may be configured to be used as escape interconnects between an integrated device and a substrate. An escape interconnect may be an interconnect that is located at least partially underneath an integrated device and is coupled to a solder interconnect of the integrated device. For the purpose, other interconnects of the substrate 102 are not necessarily shown in FIG. 3.

The use of a substrate that includes both a plurality of interconnects (e.g., second plurality of interconnects) and a plurality of high-density interconnects (e.g., first plurality of interconnects) allows for a cost-effective fabrication of a substrate that can provide high-density interconnects where it is needed. As will be further described below, an embedded trace substrate (ETS) process may be used to fabricate the plurality of high-density interconnects, which is then implemented with the fabrication of a cored substrate (which may be more cost effective, but may not be able to produce high-density interconnects). As used in the disclosure, high-density interconnects may be interconnects that have width and/or spacing that is less than 5 micrometers. As used in the disclosure, high-density interconnects may be interconnects that have minimum width and/or minimum spacing that is/are less than other interconnects of a substrate. As used in the disclosure, high-density interconnects may be interconnects that have a width and/or a spacing that is/are less than other interconnects of a substrate. In some implementations, the high-density interconnects of a substrate may be a first plurality of interconnects of the substrate, and other interconnects (e.g., non-high density interconnects) of the substrate may be a second plurality of interconnects of the substrate. In some implementations, high-density interconnects of a substrate may be similar to interconnects (e.g., non-high density interconnects) of a substrate. However, the high-density interconnects may have improved width and/or spacing, which allows for and enables higher density routing in a substrate.

It is noted than a package may include more than two integrated devices, and that the plurality of high-density interconnects 129 may be used in conjunction with more than two integrated devices. The description and disclosure of FIG. 3 may be applicable to the package 200 and/or the substrate 202.

An integrated device (e.g., 104, 304) may include a die (e.g., semiconductor bare die). The integrated device may include a power management integrated circuit (PMIC). The integrated device may include intergrated circuits. The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filters, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 104, 106, 406) may include at least one electronic circuit (e.g., first electronic circuit, second electronic circuit, etc. . . . ).

Having described various packages, a method for fabricating high-density interconnects will now be described below.

### Exemplary Sequence for Fabricating High Density Interconnects

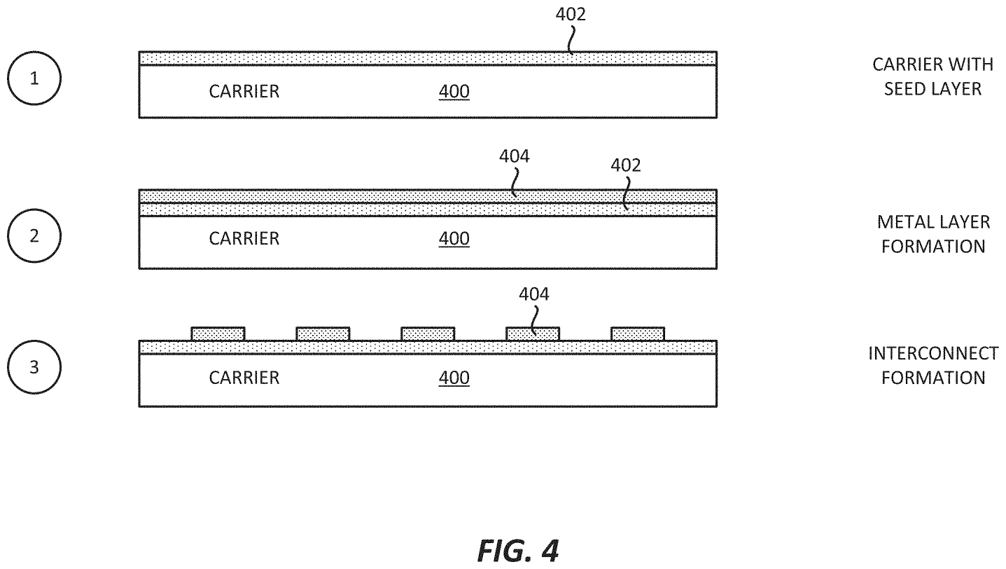

FIG. 4 illustrates an exemplary sequence for providing or fabricating high-density interconnects. In some implementations, the sequence of FIG. 4 may be used to provide or fabricate the plurality of high-density interconnects 129. However, the process of FIG. 4 may be used to fabricate any high-density interconnects described in the disclosure.

It should be noted that the sequence of FIG. 4 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 illustrates a state after a carrier 400 with a seed layer 402 is provided. Different implementations may use different materials for the carrier 400. The carrier 400 may include a substrate, glass, quartz and/or carrier tape. The seed layer 402 may include copper (e.g., copper foil).

Stage 2 illustrates a state after a metal layer 404 is formed over the seed layer 402 and/or the carrier 400. A plating process may be used to form the metal layer 404.

Stage 3 illustrates a state after high-density interconnects are formed (e.g., patterned) from the metal layer 404. The high-density interconnects formed from the metal layer 404 may represent the plurality of high-density interconnects 129. A patterning and/or an etching process may be used to pattern and remove portions of the metal layer 404 to form the high-density interconnects. In some implementations, the metal layer 404 may be patterned to form interconnects that are not high-density interconnects. In some implementations, the metal layer 404 may be patterned to include a plurality of high-density interconnects 129 and a plurality of interconnects (e.g., interconnects from the plurality of interconnects 125).

Stage 3 may illustrate an embedded trace substrate (ETS) layer that includes a plurality of high-density interconnects, which can be implemented with a cored substrate. It is noted that in some implementations, the high-density interconnects may be formed on both sides of the carrier, resulting in two ETS layers formed on the carrier. Each ETS layer may be decoupled from the carrier and separately implemented with a cored substrate.

In some implementations, a dielectric layer 406 may be formed over the carrier 400, the seed layer 402 and/or the high-density interconnects formed from the metal layer 404. A deposition and/or lamination process may be used to form the dielectric layer 406.

### Exemplary Flow Diagram of a Method for Fabricating High Density Interconnects

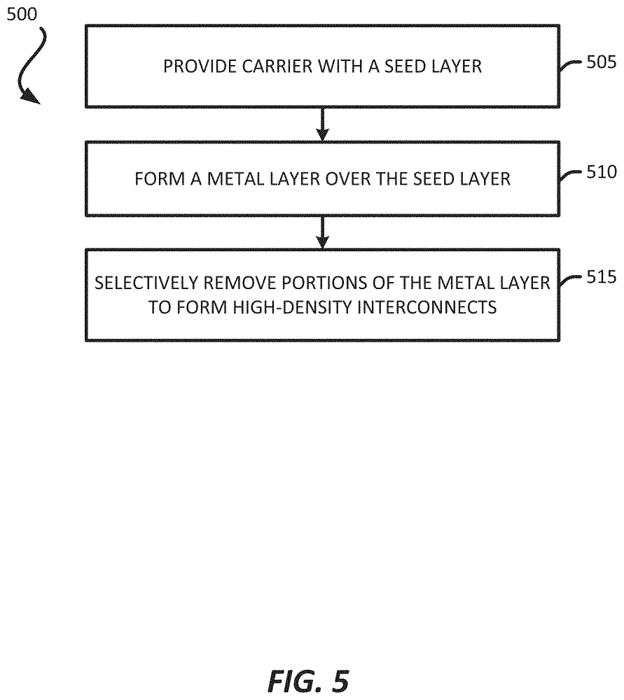

FIG. 5 illustrates an exemplary flow diagram of a method 500 for providing or fabricating high-density interconnects. In some implementations, the method 500 of FIG. 5 may be used to provide or fabricate the plurality of high-density interconnects 129 described in the disclosure. However, the method 500 may be used to provide or fabricate any high-density interconnects described in the disclosure.

It should be noted that the method of FIG. 5 may combine one or more processes in order to simplify and/or clarify the method for providing or fabricating high-density interconnects. In some implementations, the order of the processes may be changed or modified.

The method provides (at 505) a carrier (e.g., 400) with a seed layer (e.g., 402). Different implementations may use different materials for the carrier. The carrier may include a substrate, glass, quartz and/or carrier tape. The seed layer 402 may include copper (e.g., copper foil). Stage 1 of FIG. 4 illustrates and describes an example of providing a carrier with a seed layer.

The method forms (at 510) a metal layer (e.g., 404) over the seed layer (e.g., 402). A plating process (e.g., electroless plating) may be used to form the metal layer 404. Stage 2 of FIG. 4 illustrates and describes an example of a metal layer formed and patterned over a seed layer.

The method selectively removes (at 515) portions of the metal layer (e.g., 404) to form high-density interconnects. A patterning and/or an etching process may be used to pattern and remove portions of the metal layer 404 to form the high-density interconnects. In some implementations, the metal layer 404 may be patterned to include a plurality of high-density interconnects 129 and/or a plurality of interconnects (e.g., interconnects from the plurality of interconnects 125). Stage 3 of FIG. 4 illustrates and describes an example of forming high-density interconnects.

The method may form a dielectric layer (e.g., 406) over a carrier (e.g., 400), a seed layer (e.g., 402) and/or high-density interconnects formed from a metal layer (e.g., 404). A deposition and/or lamination process may be used to form the dielectric layer 406.

Exemplary Sequence for Fabricating a Substrate with High-Density Interconnects

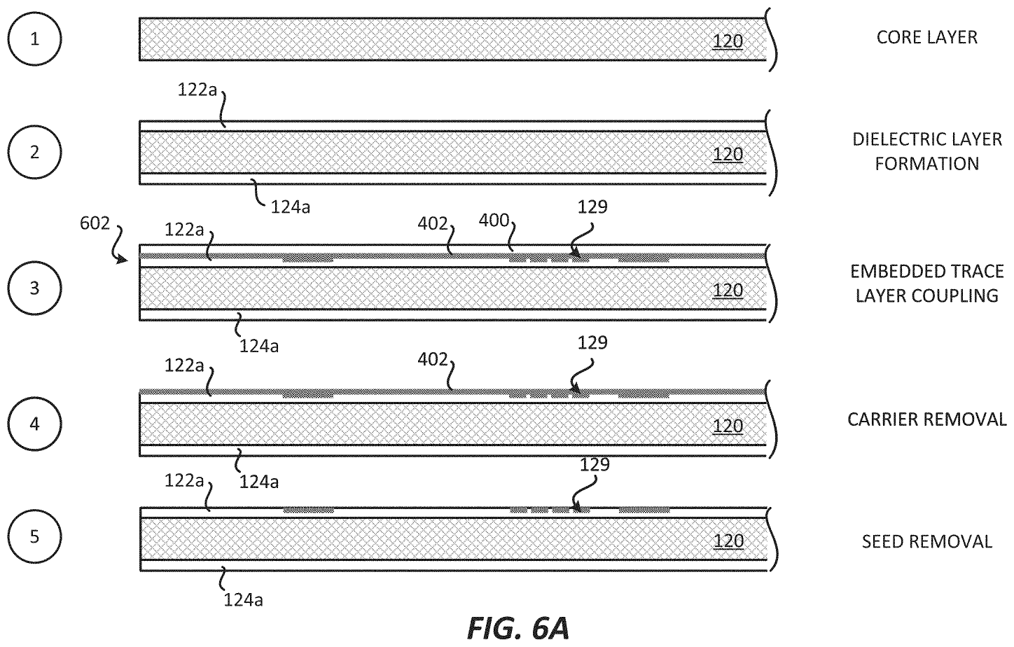

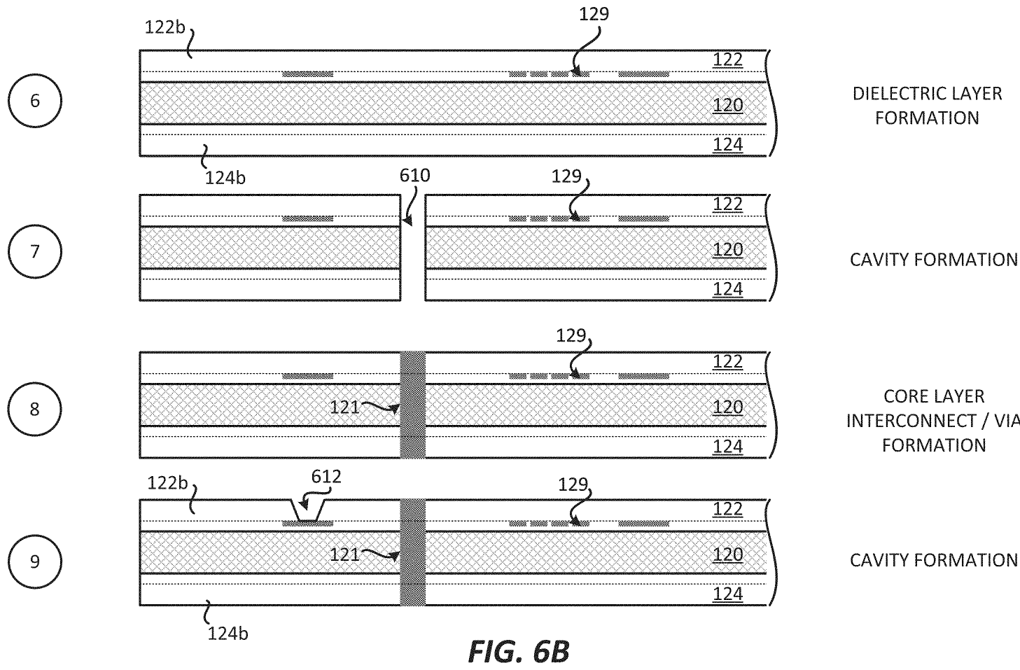

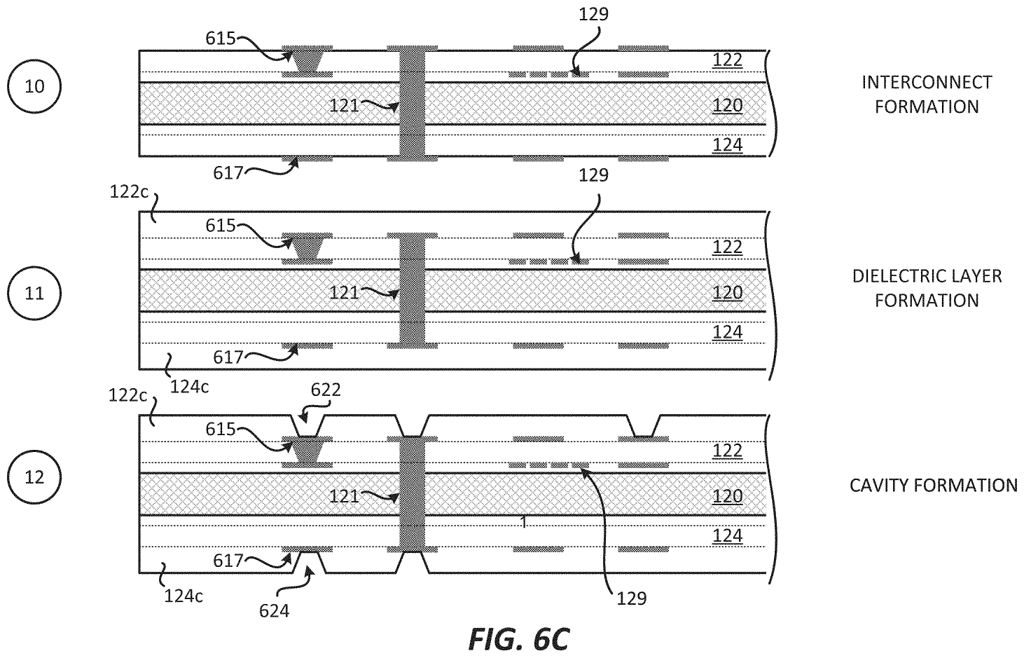

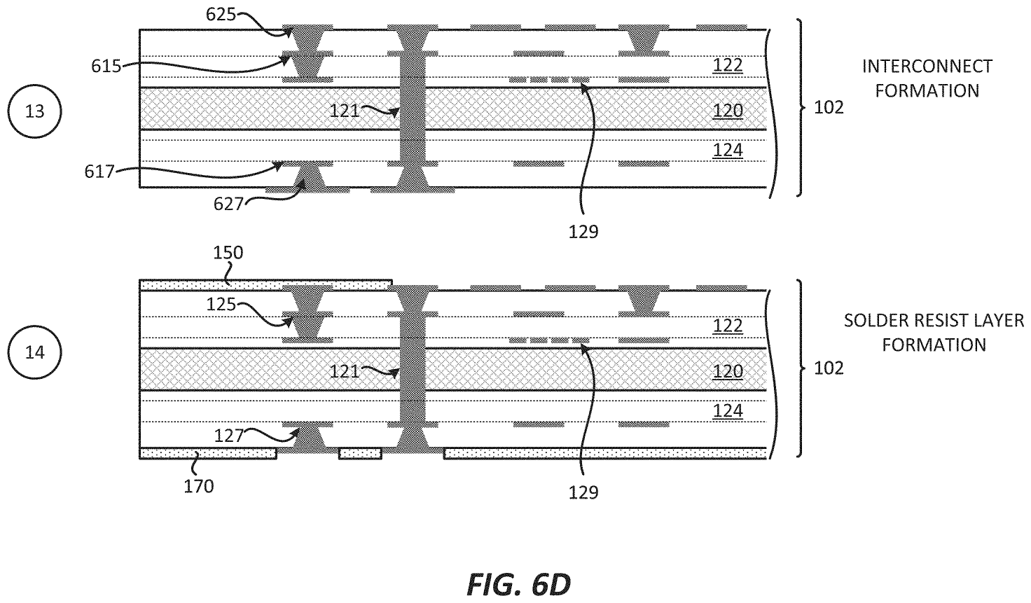

FIGS. 6A-6D illustrate an exemplary sequence for providing or fabricating a cored substrate that includes high-density interconnects. In some implementations, the sequence of FIGS. 6A-6D may be used to provide or fabricate the substrate 102 of FIG. 1 or any of the substrates described in the disclosure.

It should be noted that the sequence of FIGS. 6A-6D may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 6A, illustrates a state after a core layer 120 is provided. The core layer 120 may include silicon, glass, glass fiber with resin, quartz, epoxy, or combinations thereof. However, the core layer 120 may include different materials. In some implementations, the core layer 120 may include a seed layer on both or either side of the core layer 120.

Stage 2 illustrates a state after (i) a dielectric layer 122a is formed and coupled to a first surface of the core layer 120, and (ii) a dielectric layer 124a is formed and coupled to a second surface of the core layer 120. A lamination process and/or a deposition process may be used to form the dielectric layer 122a and the dielectric layer 124a.

Stage 3 illustrates a state after a first embedded trace substrate (ETS) layer 602 is coupled to the core layer 120. A lamination process may be used to couple the first ETS layer 602 to a first surface of the core layer 120. The first ETS layer 602 may include a carrier 400, a seed layer 402, a plurality of high-density interconnects 129. The first ETS layer 602 is coupled to the core layer 120 through the dielectric layer 122a. The plurality of high-density interconnects 129 may be located in the dielectric layer 122a. The dielectric layer 122a may considered part of the first ETS layer 602. It is noted that the first ETS layer may include high-density interconnects (e.g., 129) and non-high-density interconnects (e.g., interconnects from the plurality of interconnects 125). An example of fabricating an ETS layer is described in FIG. 4.

Stage 4 illustrate a state after the carrier 400 from the first ETS layer 602 is removed. The carrier 400 may be detached and/or grinded off. However, the carrier 400 may be decoupled from the seed layer 402 differently.

Stage 5 illustrates a state after the seed layer 402 from the first ETS layer 602 is removed. An etching process may be used to remove the seed layer(s) 402. Removing the seed layer 402 may leave the dielectric layer 122a, the plurality of high-density interconnects 129. If the ETS layer 602 includes non-high-density interconnects, the non-high-density interconnects would be there as well.

Stage 6, as shown in FIG. 6B, illustrates a state after a dielectric layer 122b is formed over the dielectric layer 122a, and a dielectric layer 124b is formed over the dielectric layer 124b. A deposition process and/or lamination process may be used to form dielectric layers 122b and 124b.

Stage 7 illustrates a state after at least one cavity 610 is formed in the dielectric layer 122 (which includes the dielectric layers 122a and 122b), the core layer 120, the dielectric layer 124 (which includes the dielectric layers 124a and 124b). The at least one cavity 610 may be formed through a laser process and/or a drilling process.

Stage 8 illustrates a state after at least one core interconnect 121 is formed in the at least one cavity 610. A plating process may be used to form the at least one core interconnect 121. However, different implementations may use different processes for forming the at least one core interconnect 121. For example, the at least one core interconnect 121 may be filled with a metal (e.g., metal paste). In some implementations, the method that is used may depend on the thickness of the core layer 120. In some implementations, for core layers up to 250 micrometers thick, filling/pasting method may be used to form the at least one core interconnect 121. When the thickness of the core layer 120 is greater than 400 micrometers, some implementations may use a plating process to form the at least one core interconnect 121. The at least one core interconnect 121 may extend through the dielectric layer 122, the core layer 120 and the dielectric layer 124. The at least one core interconnect 121 may include at least one core via (e.g., core via interconnect) that extends through the dielectric layer 122, the core layer 120 and the dielectric layer 124.

Stage 9 illustrates a state after a plurality of cavities 612 is formed in the dielectric layer 122b. In some implementations, a plurality of cavities may be formed in the dielectric layer 124b. A laser process (e.g., laser drilling, laser ablation) and/or etching process may be used to form the plurality of cavities 612.

Stage 10, as shown in FIG. 6C, illustrates a state after a plurality of interconnects 615 is formed over and coupled to the dielectric layer 122 and the plurality of cavities 612. The plurality of interconnects 615 may be coupled to the plurality of high-density interconnects 129. The plurality of interconnects 615 may be coupled to other interconnect on the same metal layer as the plurality of high-density interconnects 129. The plurality of interconnects 615 may be coupled to the at least one core interconnect 121. Stage 10 also illustrates a state after a plurality of interconnects 617 is formed over and coupled the dielectric layer 124 and the plurality of cavities (if present). The plurality of interconnects 617 may be coupled to the at least one core interconnect 121. A patterning process, a stripping process and/or a plating process may be used to form the plurality of interconnects 615 and the plurality of interconnects 617.

Stage 11 illustrates a state after a dielectric layer 122c is formed over and coupled to a first surface of dielectric layer 122b, and a dielectric layer 124c is formed over and coupled to a second surface of the dielectric layer 124b. A deposition process and/or lamination process may be used to form dielectric layers 122c and 124c.

Stage 12 illustrates a state after a plurality of cavities 622 is formed in the dielectric layer 122c, and a plurality of cavities 624 is formed in the dielectric layer 124c. A laser process (e.g., laser drilling, laser ablation) and/or etching process may be used to form the plurality of cavities 622 and the plurality of cavities 624.

Stage 13, as shown in FIG. 6D, illustrates a state after a plurality of interconnects 625 is formed over and coupled to the dielectric layer 122 (which may include dielectric layers 122a, 122b and 122c) and the plurality of cavities 622. The plurality of interconnects 625 may be coupled to the plurality of interconnects 615. Stage 12 also illustrates a state after a plurality of interconnects 627 is formed over and coupled the dielectric layer 124 (which may include dielectric layers 124a, 124b and 124c) and the plurality of cavities 624. The plurality of interconnects 627 may be coupled to the plurality of interconnects 617. A patterning process, a stripping process and/or a plating process may be used to form the plurality of interconnects 625 and the plurality of interconnects 627.

It is noted that additional dielectric layers and additional interconnects may be formed by repeating Stages 11-13 of FIGS. 6C-6D, as described above.

Stage 14 illustrates a state after (i) the solder resist layer 150 is formed over the dielectric layer 122, and (ii) the solder resist layer 170 is formed over the dielectric layer 124. A deposition process may be used the solder resist layer 150 and the solder resist layer 170. Stage 13 may illustrate an example of the substrate 102 that includes a plurality of high-density interconnects 129 fabricated using a process that includes an ETS process. The substrate 102 may be a cored substrate that includes an ETS layer with high-density interconnects 129.

Exemplary Flow Diagram of a Method for Fabricating a Substrate with High-Density Interconnects

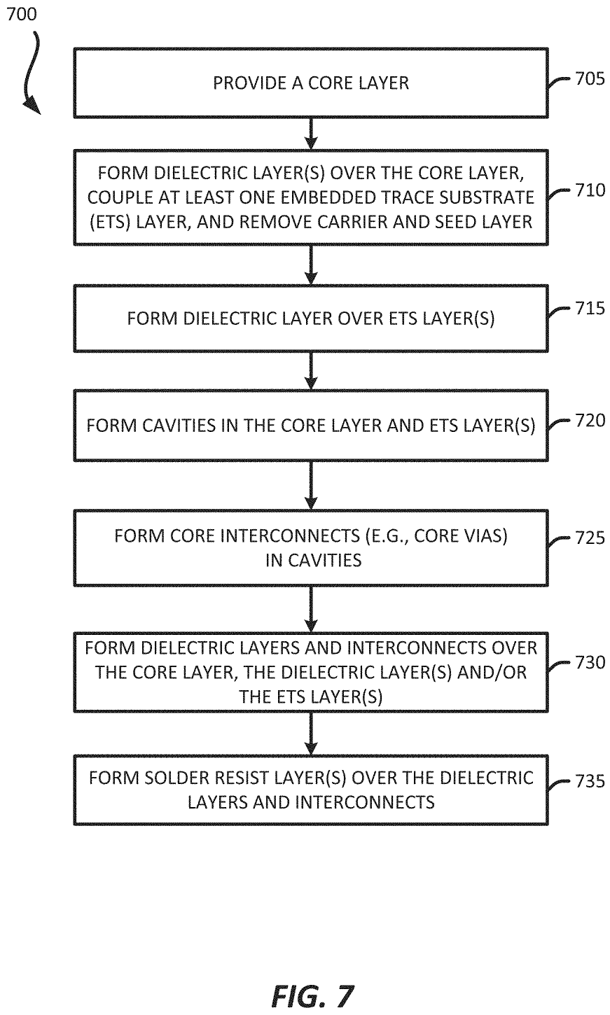

In some implementations, fabricating a substrate includes several processes. FIG. 7 illustrates an exemplary flow diagram of a method 700 for providing or fabricating a substrate with high density interconnects. In some implementations, the method 700 of FIG. 7 may be used to provide or fabricate the substrate of FIG. 1. For example, the method of FIG. 7 may be used to fabricate the substrate 102. However, the method of FIG. 7 may be used fabricate any substrate (e.g., 202) in the disclosure.

It should be noted that the method 700 of FIG. 7 may combine one or more processes in order to simplify and/or clarify the method for providing or fabricating a substrate. In some implementations, the order of the processes may be changed or modified.

The method provides (at 705) a core layer (e.g., 120). The core layer 120 may include silicon, glass, glass fiber with resin, quartz, epoxy, or combinations thereof. However, the core layer 120 may include different materials. In some implementations, seed layers may be located over surface(s) of the core layer 120. Stage 1 of FIG. 6A, illustrates and describes an example of providing a core layer.

The method forms (at 710) dielectric layers (e.g., 122a, 124a) over the first surface and the second surface of the core layer 120. A deposition and/or lamination process may be used to form the dielectric layers. Stage 2 of FIG. 6A illustrates and describes an example of forming dielectric layers over a core layer.

The method couples (at 710) at least one embedded trace substrate (ETS) layer comprising high-density interconnects to the core layer (e.g., 120). For example, a first embedded trace substrate (ETS) layer 602 may be coupled to the core layer 120. A lamination process may be used to couple the first ETS layer 602 to a first surface of the core layer 120. The first ETS layer 602 may include a carrier 400, a seed layer 402, a plurality of high-density interconnects 129 An example of forming an ETS layer is described in FIG. 4. Stage 3 of FIG. 6A illustrates and describes an example of at least one ETS layer coupled to a core layer through a dielectric layer

After the ETS layer(s) is coupled to a core layer, the method may remove (at 710) the carrier(s) and the seed layer(s). The carrier may be detached and the seed layer may be etched out. Stages 4 and 5 of FIG. 6A illustrate and describe an example of removing a carrier and a seed layer.

The method forms (at 715) dielectric layer(s) (e.g., 122b, 124b) over the ETS layer(s) and/or dielectric layers (e.g., 122a, 124b). A deposition process and/or lamination process may be used to form dielectric layers 122b and 124b. Stage 6 of FIG. 6B, illustrates and describes an example of forming a dielectric layer over an ETS layer.

The method forms (at 720) at least one cavity (e.g., 610) in the core layer and at least one dielectric layer. For example, the method may form cavities (e.g., 610) in the dielectric layer 122, the core layer 120 and the dielectric layer 124. The at least one cavity 610 may be formed through a laser process and/or a drilling process. Stage 7 of FIG. 6B illustrates and describes an example of forming a cavity in the core layer and dielectric layer(s).

The method forms (at 725) at least one core interconnect (e.g., 121) in the at least one cavity 610. A plating process may be used to form the at least one core interconnect 121. However, different implementations may use different processes for forming the at least one core interconnect 121. The at least one core interconnect 121 may extend through the dielectric layer 122, the core layer 120 and the dielectric layer 124. The at least one core interconnect 121 may include at least one core via that extends through the dielectric layer 122, the core layer 120 and the dielectric layer 124. Stage 8 of FIG. 6B illustrates and describes an example of forming at least one core interconnect.

The method forms (at 730) dielectric layers and interconnects over the core layer, the dielectric layers (e.g., 122a, 124a) and/or the ETS layer(s). Forming dielectric layer(s) (e.g., 122b, 122c, 124b, 124c) may include a deposition process and/or a lamination process. Forming dielectric layers may include forming cavities (e.g., 612,) in the dielectric layer(s). Forming interconnects (e.g., 615, 617, 625, 627) includes forming interconnects over dielectric layer(s). A patterning process, a stripping process and/or a plating process may be used to form the plurality of interconnects (e.g., 615, 617, 625, 627). Stages 9-13 of FIGS. 6B-6D illustrate and describe examples of forming several dielectric layers and interconnects. It is noted that the forming a dielectric layer, forming a cavity and forming interconnects may be iteratively repeated for as many metal layers as needed. It is noted that in some implementations, one or more ETS layer(s) may be formed over the dielectric layers and interconnects.

The method forms (at 735) at least one solder resist layer (e.g., 150, 170) over dielectric layer(s). For example, a solder resist layer 150 may be formed over the dielectric layer 122, and (ii) a solder resist layer 170 may be formed over the dielectric layer 124. A deposition process may be used the solder resist layer 150 and the solder resist layer 170. Stage 14 of FIG. 6D illustrates and describes an example of forming at least one solder resist layer.

### Exemplary Sequence for Fabricating a Package That Includes a Substrate Having High-Density Interconnects

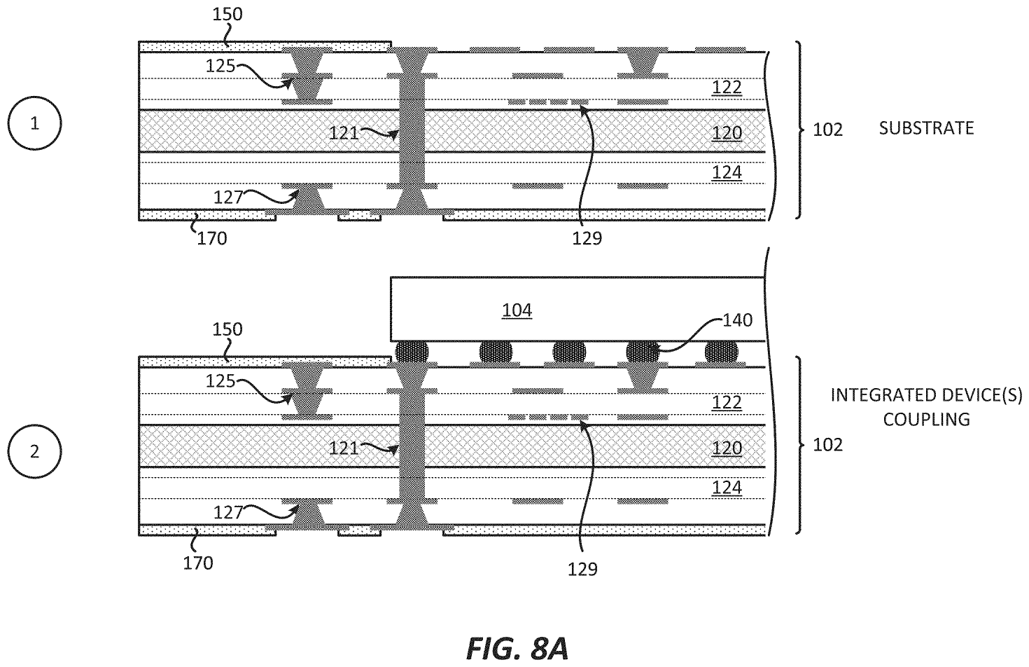

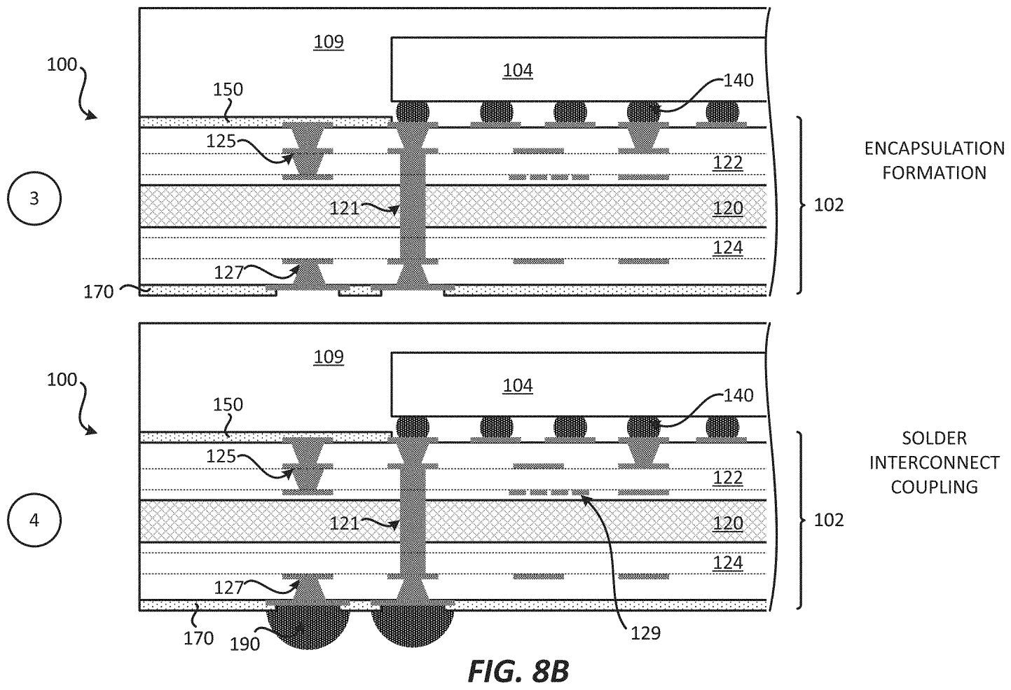

FIGS. 8A-8B illustrate an exemplary sequence for providing or fabricating a package that includes a substrate with high-density interconnects. In some implementations, the sequence of FIGS. 8A-8B may be used to provide or fabricate the package 100 of FIG. 1, or any of the packages (e.g., 200) described in the disclosure.

It should be noted that the sequence of FIGS. 8A-8B may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure. Different implementations may fabricate a package differently.

Stage 1, as shown in FIG. 8A, illustrates a state after a substrate 102 is provided. The substrate 102 may be provided using the process described in FIG. 6A-6D. The substrate 102 includes the core layer 120, the at least one first dielectric layer 122, the at least one dielectric layer 124, the plurality of interconnects 125, the plurality of interconnects 127, the at least one core interconnect 121, the plurality of high-density interconnects 129, the solder resist layer 150 and the solder resist layer 170.

Stage 2 illustrates a state after an integrated device 104 is coupled to the substrate 102 through the plurality of solder interconnects 140. A pick and place process may be used to place the integrated device 104 over a first surface of the substrate 102. A solder reflow process may be used to couple the integrated device 104 to the substrate 102. The integrated device 104 may be coupled to the plurality of interconnects 125 through the plurality of solder interconnects 140. Different implementations may couple a different number of integrated devices to the substrate 102.

Stage 3, as shown in FIG. 8B, illustrates a state after an encapsulation layer 109 is provided. The encapsulation layer 109 may encapsulate the integrated device 104. The encapsulation layer 109 may be coupled to a surface of the substrate 102. The encapsulation layer 109 may be formed over the substrate 102 and integrated device 104. The encapsulation layer 109 may include a mold, a resin and/or an epoxy. The encapsulation layer 109 may be a means for encapsulation. A compression and transfer molding process, a sheet molding process, or a liquid molding process may be used to form the encapsulation layer.

Stage 4 illustrates a state a plurality of solder interconnects 190 is coupled to the substrate 102. A solder reflow process may be used to couple the plurality of solder interconnects 190 to the substrate 102. Stage 4 may illustrate the package 100 that includes the substrate 102, the integrated device 104 and the encapsulation layer 109.

Exemplary Flow Diagram of a Method for Fabricating a Package Having a Substrate with High-Density Interconnects

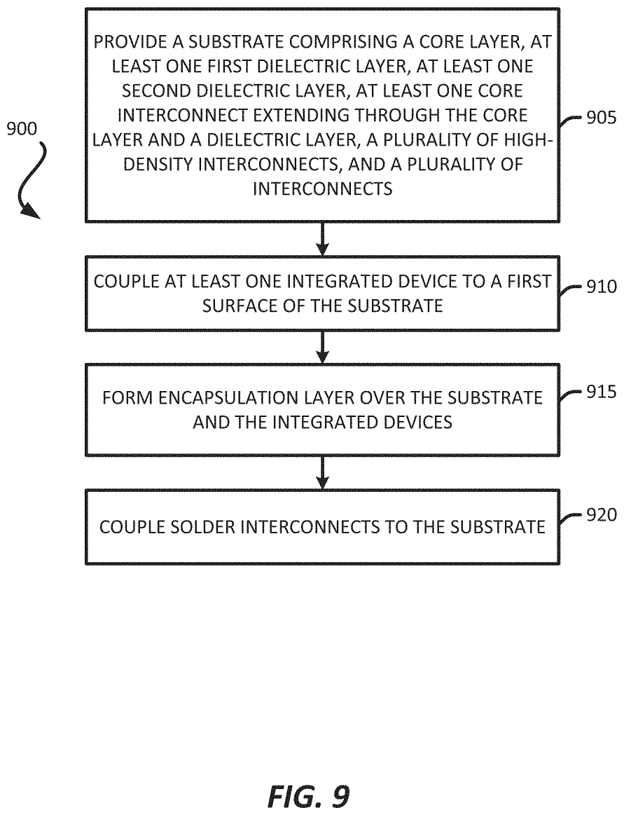

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 100 of FIG. 1. For example, the method 900 of FIG. 9 may be used to fabricate the package 100. However, the method 900 of FIG. 9 may be used fabricate any package (e.g., 200) in the disclosure.

It should be noted that the method of FIG. 9 may combine one or more processes in order to simplify and/or clarify the method for providing or fabricating a package. In some implementations, the order of the processes may be changed or modified.

The method provides (at 905) a substrate (e.g., 102, 202) that includes high-density interconnects (e.g., 129). The plurality of high-density interconnects may be fabricated using an ETS process. The substrate may include a core layer 120, at least one dielectric layer (e.g., 122, 124), a plurality of interconnects (e.g., 125, 127), at least one core interconnect 121, a plurality of high-density interconnects 129, and at least one solder resist layer (e.g., 150, 170). The substrate may be provided using the process described in FIGS. 6A-6D. Stage 1 of FIG. 8A illustrates and describes an example of a substrate with high-density interconnects.

The method couples (at 910) at least one integrated device (e.g., 104, 304) to the substrate (e.g., 102, 202). A pick and place process may be used to place the at least one integrated device over a first surface of the substrate. A solder reflow process may be used to couple the integrated device to the substrate. Different implementations may couple a different number of integrated devices to the substrate. Stage 2 of FIG. 8A illustrates and describes an example of at least one integrated device coupled to a substrate.

The method forms (at 915) an encapsulation layer (e.g., 109) over the substrate (e.g., 102). The encapsulation layer (e.g., 109) may encapsulate the at least one integrated device (e.g., 104). The encapsulation layer may be coupled to a surface of the substrate. The encapsulation layer may include a mold, a resin and/or an epoxy. A compression and transfer molding process, a sheet molding process, or a liquid molding process may be used to form the encapsulation layer. Stage 3 of FIG. 8B illustrates and describes an example of an encapsulation layer that is located over a substrate.

The method couples (at 920) a plurality of solder interconnects (e.g., 190) to the substrate (e.g., 102). A solder reflow process may be used to couple the plurality of solder interconnects to the substrate. Stage 4 of FIG. 8B illustrates and describes an example solder interconnects coupled to a substrate.

### Exemplary Electronic Devices

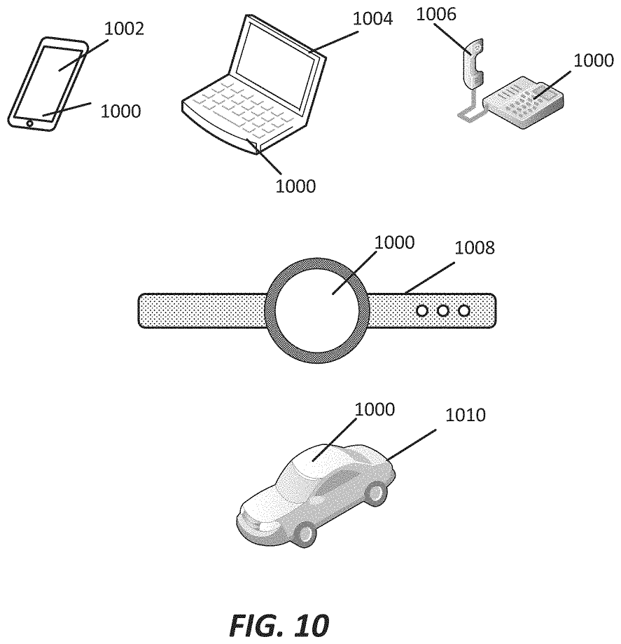

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6D, 7, 8A-8B, and/or 9-10 may be rearranged and/or combined into a single component, process, feature or function or embodied in several components, processes, or functions. Additional elements, components, processes, and/or functions may also be added without departing from the disclosure. It should also be noted FIGS. 1-5, 6A-6D, 7, 8A-8B, and/or 9-10 and its corresponding description in the present disclosure is not limited to dies and/or ICs. In some implementations, FIGS. 1-5, 6A-6D, 7, 8A-8B, and/or 9-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object that is coupled to another object may be coupled to part of the object or all of the object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. There may or may not be one or more interfaces between interconnects An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1. A package comprising a substrate and an integrated device coupled to the substrate. The substrate comprising a core layer comprising a first surface and a second surface; at least one first dielectric layer coupled to the first surface of the core layer; at least one second dielectric layer coupled to the second surface of the core layer; at least one core interconnect that extends through the core layer and at least one dielectric layer from the at least first dielectric layer and/or the at least one second dielectric layer; a plurality of high-density interconnects comprising a first minimum width and a first minimum spacing; and a plurality of interconnects comprising a second minimum width and a second minimum spacing. The second minimum width is greater than the first minimum width. The second minimum spacing is greater than the first minimum spacing.

Aspect 2: The package of aspect 1, wherein the plurality of high-density interconnects comprises a width of about 3-4 micrometers, and wherein the plurality of high-density interconnects comprises a spacing of about 3-4 micrometers.

Aspect 3: The package of aspects 1 through 2, wherein the plurality of interconnects comprises a width of about 5 micrometers or greater, and wherein the plurality of interconnects comprises a spacing of about 5 micrometers or greater.

Aspect 4: The package of aspects 1 through 3, wherein the plurality of high-density interconnects comprises a thickness of about 0.5-1 micrometer.

Aspect 5: The package of aspects 1 through 4, further comprising a second integrated device coupled to the substrate, wherein the second integrated device is configured to be electrically coupled to the integrated device through the plurality of high-density interconnects.

Aspect 6: The package of aspect 5, wherein the plurality of high-density interconnects is configured as a plurality of bridge interconnects for electrical communication between the integrated device and the second integrated device.

Aspect 7: The package of aspects 1 through 6, wherein the plurality of high-density interconnects is located on a metal layer of the substrate.

Aspect 8: The package of aspect 7, wherein the metal layer of the substrate is a particular metal layer located over the core layer of the substrate.

Aspect 9: A substrate comprising a core layer comprising a first surface and a second surface; at least one first dielectric layer coupled to the first surface of the core layer; at least one second dielectric layer coupled to the second surface of the core layer; at least one core interconnect that extends through the core layer and at least one dielectric layer from the at least first dielectric layer and/or the at least one second dielectric layer; a plurality of high-density interconnects comprising a first minimum width and a first minimum spacing; and a plurality of interconnects comprising a second minimum width and a second minimum spacing. The second minimum width is greater than the first minimum width. The second minimum spacing is greater than the first minimum spacing.

Aspect 10: The substrate of aspect 9, wherein the plurality of high-density interconnects comprises a width of about 3-4 micrometers, and wherein the plurality of high-density interconnects comprises a spacing of about 3-4 micrometers.

Aspect 11: The substrate of aspects 9 through 10, wherein the plurality of interconnects comprises a width of about 5 micrometers or greater, and wherein the plurality of interconnects comprises a spacing of about 5 micrometers or greater.

Aspect 12: The substrate of aspects 9 through 11, wherein the plurality of high-density interconnects comprises a thickness of about 0.5-1 micrometer.

Aspect 13: The substrate of aspects 9 through 12, further comprising a second integrated device coupled to the substrate, wherein the second integrated device is configured to be electrically coupled to the integrated device through the plurality of high-density interconnects.

Aspect 14: The substrate of aspect 13, wherein the plurality of high-density interconnects is configured as a plurality of bridge interconnects for electrical communication between the integrated device and the second integrated device.

Aspect 15: The substrate of aspects 9 through 14, wherein the plurality of high-density interconnects is located on a metal layer of the substrate.

Aspect 16: An apparatus comprising a substrate and an integrated device coupled to the substrate. The substrate comprising a core layer comprising a first surface and a second surface; at least one first dielectric layer coupled to the first surface of the core layer; at least one second dielectric layer coupled to the second surface of the core layer; means for core interconnection that extends through the core layer and at least one dielectric layer from the at least first dielectric layer and/or the at least one second dielectric layer; means for high-density interconnection comprising a first minimum width and a first minimum spacing; and means for interconnection comprising a second minimum width and a second minimum spacing. The second minimum width is greater than the first minimum width. The second minimum spacing is greater than the first minimum spacing.

Aspect 17: The apparatus of aspect 16, wherein the means for high-density interconnection comprises a width of about 3-4 micrometers, wherein the means for high-density interconnection comprises a spacing of about 3-4 micrometers, wherein the means for interconnection comprises a width of about 5 micrometers or greater, and wherein the means for interconnection comprises a spacing of about 5 micrometers or greater.

Aspect 18: The apparatus of aspects 16 through 17, wherein the means for high-density interconnection comprises a thickness of about 0.5-1 micrometer.

Aspect 19: The apparatus of aspects 16 through 18, further comprising a second integrated device coupled to the substrate, wherein the second integrated device is configured to be electrically coupled to the integrated device through the means for high-density interconnection.

Aspect 20: The apparatus of aspects 16 through 19, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a substrate. The method provides a core layer comprising a first surface and a second surface. The method provides at least one first dielectric layer and a plurality of high-density interconnects over the first surface of the core layer, wherein the plurality of high-density interconnects comprises a first minimum width and a first minimum spacing. The method forms at least one second dielectric layer over the second surface of the core layer. The method forms at least one core interconnect that extends through the core layer and at least one dielectric layer from the at least first dielectric layer and/or the at least second dielectric layer. The method forms a plurality of interconnects comprising a second minimum width and a second minimum spacing. The second minimum width is greater than the first minimum width. The second minimum spacing is greater than the first minimum spacing.

Aspect 22: The method of aspect 21, wherein the plurality of high-density interconnects comprises a width of about 3-4 micrometers, and wherein the plurality of high-density interconnects comprises a spacing of about 3-4 micrometers.

Aspect 23: The method of aspects 21 through 22, wherein the plurality of interconnects comprises a width of about 5 micrometers or greater, and wherein the plurality of interconnects comprises a spacing of about 5 micrometers or greater.

Aspect 24: The method of aspects 21 through 23, wherein the plurality of high-density interconnects comprises a thickness of about 0.5-1 micrometer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
a core layer comprising a first surface and a second surface;
at least one first dielectric layer coupled to the first surface of the core layer;
at least one second dielectric layer coupled to the second surface of the core layer;
at least one core interconnect that extends through the core layer and at least one dielectric layer from the at least first dielectric layer and/or the at least one second dielectric layer;
a plurality of high-density interconnects comprising a first minimum width and a first minimum spacing; and
a plurality of interconnects comprising a second minimum width and a second minimum spacing,
wherein the second minimum width is greater than the first minimum width, and
wherein the second minimum spacing is greater than the first minimum spacing, and
an integrated device coupled to the substrate.

2. The package of claim 1,
wherein the plurality of high-density interconnects comprises a width of about 3-4 micrometers, and
wherein the plurality of high-density interconnects comprises a spacing of about 3-4 micrometers.

3. The package of claim 1,
wherein the plurality of interconnects comprises a width of about 5 micrometers or greater, and
wherein the plurality of interconnects comprises a spacing of about 5 micrometers or greater.

4. The package of claim 1, wherein the plurality of high-density interconnects comprises a thickness of about 0.5-1 micrometer.

5. The package of claim 1, further comprising a second integrated device coupled to the substrate, wherein the second integrated device is configured to be electrically coupled to the integrated device through the plurality of high-density interconnects.

6. The package of claim 5, wherein the plurality of high-density interconnects is configured as a plurality of bridge interconnects for electrical communication between the integrated device and the second integrated device.

7. The package of claim 1, wherein the plurality of high-density interconnects is located on a metal layer of the substrate.

8. The package of claim 7, wherein the metal layer of the substrate is a particular metal layer located over the core layer of the substrate.

9. A substrate comprising:
a core layer comprising a first surface and a second surface;
at least one first dielectric layer coupled to the first surface of the core layer;
at least one second dielectric layer coupled to the second surface of the core layer;
at least one core interconnect that extends through the core layer and at least one dielectric layer from the at least first dielectric layer and/or the at least one second dielectric layer;
a plurality of high-density interconnects comprising a first minimum width and a first minimum spacing; and
a plurality of interconnects comprising a second minimum width and a second minimum spacing,
wherein the second minimum width is greater than the first minimum width, and
wherein the second minimum spacing is greater than the first minimum spacing.

10. The substrate of claim 9,
wherein the plurality of high-density interconnects comprises a width of about 3-4 micrometers, and
wherein the plurality of high-density interconnects comprises a spacing of about 3-4 micrometers.

11. The substrate of claim 9,
wherein the plurality of interconnects comprises a width of about 5 micrometers or greater, and
wherein the plurality of interconnects comprises a spacing of about 5 micrometers or greater.

12. The substrate of claim 9, wherein the plurality of high-density interconnects comprises a thickness of about 0.5-1 micrometer.

13. The substrate of claim 9, further comprising a second integrated device coupled to the substrate, wherein the second integrated device is configured to be electrically coupled to the integrated device through the plurality of high-density interconnects.

14. The substrate of claim 13, wherein the plurality of high-density interconnects is configured as a plurality of bridge interconnects for electrical communication between the integrated device and the second integrated device.

15. The substrate of claim 9, wherein the plurality of high-density interconnects is located on a metal layer of the substrate.

16. An apparatus comprising:
a substrate comprising:
a core layer comprising a first surface and a second surface;
at least one first dielectric layer coupled to the first surface of the core layer;
at least one second dielectric layer coupled to the second surface of the core layer;
means for core interconnection that extends through the core layer and at least one dielectric layer from the at least first dielectric layer and/or the at least one second dielectric layer;
means for high-density interconnection comprising a first minimum width and a first minimum spacing; and
means for interconnection comprising a second minimum width and a second minimum spacing,
wherein the second minimum width is greater than the first minimum width, and
wherein the second minimum spacing is greater than the first minimum spacing, and
an integrated device coupled to the substrate.

17. The apparatus of claim 16,
wherein the means for high-density interconnection comprises a width of about 3-4 micrometers,
wherein the means for high-density interconnection comprises a spacing of about 3-4 micrometers,
wherein the means for interconnection comprises a width of about 5 micrometers or greater, and
wherein the means for interconnection comprises a spacing of about 5 micrometers or greater.

18. The apparatus of claim 16, wherein the means for high-density interconnection comprises a thickness of about 0.5-1 micrometer.

19. The apparatus of claim 16, further comprising a second integrated device coupled to the substrate, wherein the second integrated device is configured to be electrically coupled to the integrated device through the means for high-density interconnection.

20. The apparatus of claim 16, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a substrate, comprising:
providing a core layer comprising a first surface and a second surface;
providing at least one first dielectric layer and a plurality of high-density interconnects over the first surface of the core layer, wherein the plurality of high-density interconnects comprises a first minimum width and a first minimum spacing;
forming at least one second dielectric layer over the second surface of the core layer; and
forming at least one core interconnect that extends through the core layer and at least one dielectric layer from the at least first dielectric layer and/or the at least second dielectric layer;
forming a plurality of interconnects comprising a second minimum width and a second minimum spacing,
wherein the second minimum width is greater than the first minimum width, and
wherein the second minimum spacing is greater than the first minimum spacing.

22. The method of claim 21,
wherein the plurality of high-density interconnects comprises a width of about 3-4 micrometers, and
wherein the plurality of high-density interconnects comprises a spacing of about 3-4 micrometers.

23. The method of claim 21,
wherein the plurality of interconnects comprises a width of about 5 micrometers or greater, and
wherein the plurality of interconnects comprises a spacing of about 5 micrometers or greater.

24. The method of claim 21, wherein the plurality of high-density interconnects comprises a thickness of about 0.5-1 micrometer.
